(19) United States
(12) Patent Application Publication
(10) Pub. No.: US 2018/0120377 A1
(43) Pub. Date: May 3, 2018

(54) LOGIC ANALYZER AND PROBE THEREOF

(71) Applicant: ZEROPLUS TECHNOLOGY CO., LTD., NEW TAIPEI CITY (TW)

(72) Inventor: CHIU-HAO CHENG, NEW TAIPEI CITY (TW)

(73) Assignee: ZEROPLUS TECHNOLOGY CO., LTD., NEW TAIPEI CITY (TW)

(21) Appl. No.: 15/326,440

(22) PCT Filed: May 18, 2015
(86) PCT No.: PCT/CN2015/000337

§ 371 Date: Jan. 13, 2017

(51) Int. Cl. G01R 31/3177; G01R 31/319; G01R 31/3183; G01R 31/28

(52) U.S. Cl. CPC G01R 31/3177; G01R 31/2808; G01R 31/318314; G01R 31/31905

(57) ABSTRACT

A logic analyzer includes a probe, a first transmission line, a display, a second transmission line, and a processing unit. The probe is adapted to abut against a DUT to retrieve digital signals therefrom. The first transmission line is electrically connected to the probe. The display is provided on the probe. The second transmission line is electrically connected to the display. The processing unit is electrically connected to the first transmission line and the second transmission line, and is adapted to be electrically connected to a computer. The digital signal retrieved by the probe would be transmitted to the processing unit through the first transmission line to be analyzed therein. After completing the analysis, an analysis result would be transmitted to the computer for display. Meanwhile, a part of the analysis result is transmitted to the display through the second transmission line to be displayed thereon.

### BACKGROUND OF THE INVENTION

### 1. Technical Field

The present invention relates generally to digital signal analysis, and more particularly to a logic analyzer and a probe thereof.

### 2. Description of Related Art

With advances in digital technology, electronic devices which transmit data through digital signals, such as electronic chips, image processing chips of liquid crystal displays (LCD), complementary metal-oxide semiconductors (CMOS), and charge coupled devices (CCD), are everywhere now.

During the process of research and development, logic analyzers are commonly used to retrieve digital signals outputted by an electronic device, whereby to analyze said retrieved digital signals by comparing them with a basic signal, so as to determine whether the electronic device works normally.

However, a conventional logic analyzer usually analyzes the digital signals first, and then displays the result on a computer monitor, therefore a R&D engineer may have to turn around to check the analysis result displayed on the monitor while trying to keep the probe abutting against the device under test, which is inconvenience and prone to error. In addition, when there are multiple probes used to test multiple portions at once, it is easy to confuse the test channels corresponding to the probes, which would delay the test process.

### BRIEF SUMMARY OF THE INVENTION

In view of the above, the primary objective of the present invention is to provide a logic analyzer and a probe thereof, which could help a R&D engineer to quickly and accurately realize the analysis result corresponding to each probe.

The present invention provides a logic analyzer, wherein the logic analyzer includes a probe, a first transmission line electrically connected to the probe, a display provided on the probe, a second transmission line, and a processing unit. The probe is adapted to abut against a device under test (DUT) to retrieve digital signals outputted by the DUT. The second transmission line is electrically connected to the display. The processing unit is electrically connected to the first transmission line and the second transmission line, and is adapted to be electrically connected to a computer, wherein a plurality of parameters are set in the processing unit. The processing unit receives the digital signals retrieved by the probe through the first transmission line, and analyzes the received digital signals based on the parameters set therein to generate an analysis result, which is transmitted to the computer to be displayed thereon. A part of the analysis result is transmitted to the display through the second transmission line to be shown thereon.

The present invention provides a probe for a logic analyzer, wherein the probe is adapted to abut against a device under test (DUT) to retrieve digital signals outputted by the DUT, and is adapted to transmit the digital signals to a processing unit of the logic analyzer for analyzing. The probe includes a display provided thereon, wherein a part of an analysis result generated by the processing unit is shown on the display.

With the aforementioned design, a R&D engineer could quickly and accurately realize the parameters corresponding to the retrieved digital signals through the display on the probe while using the logic analyzer.

### BRIEF DESCRIPTION OF THE SEVERAL VIEWS OF THE DRAWINGS

The present invention will be best understood by referring to the following detailed description of some illustrative embodiments in conjunction with the accompanying drawings, in which

FIG. 1 is a schematic diagram of the test system of the logic analyzer of an embodiment of the present invention; and

FIG. 2 is a perspective view of the probe of the embodiment of the present invention.

### DETAILED DESCRIPTION OF THE INVENTION

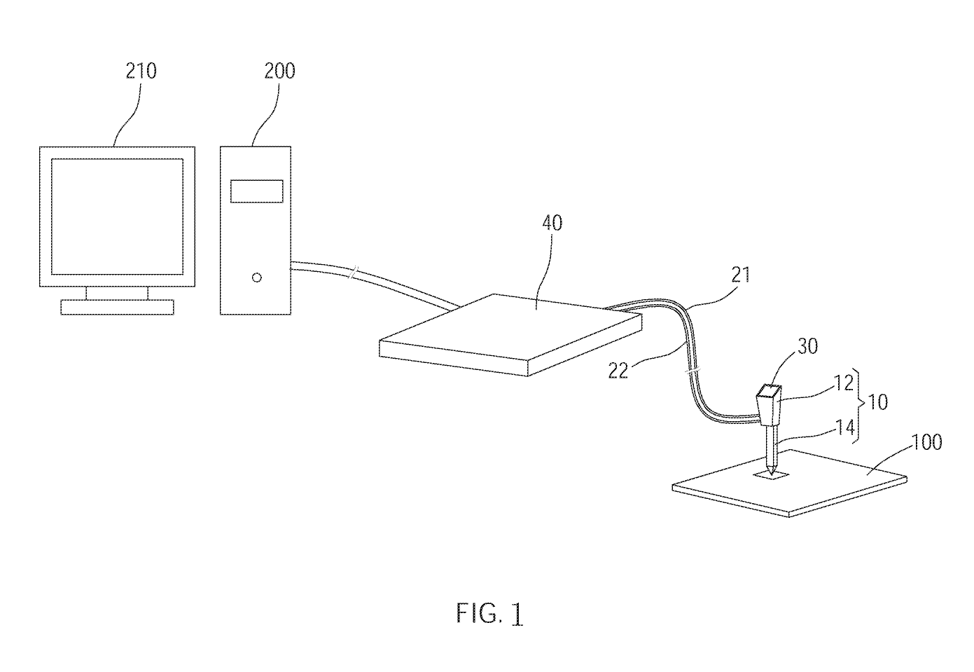

A logic analyzer of an embodiment of the present invention is illustrated in FIG. 1, which is adapted to retrieve and analyze digital signals generated by a device under test (DUT) 100, and is adapted to transmit the analysis result to a computer 200. The logic analyzer includes a probe 10, a display 30, a first transmission line 21, a second transmission line 22, and a processing unit 40.

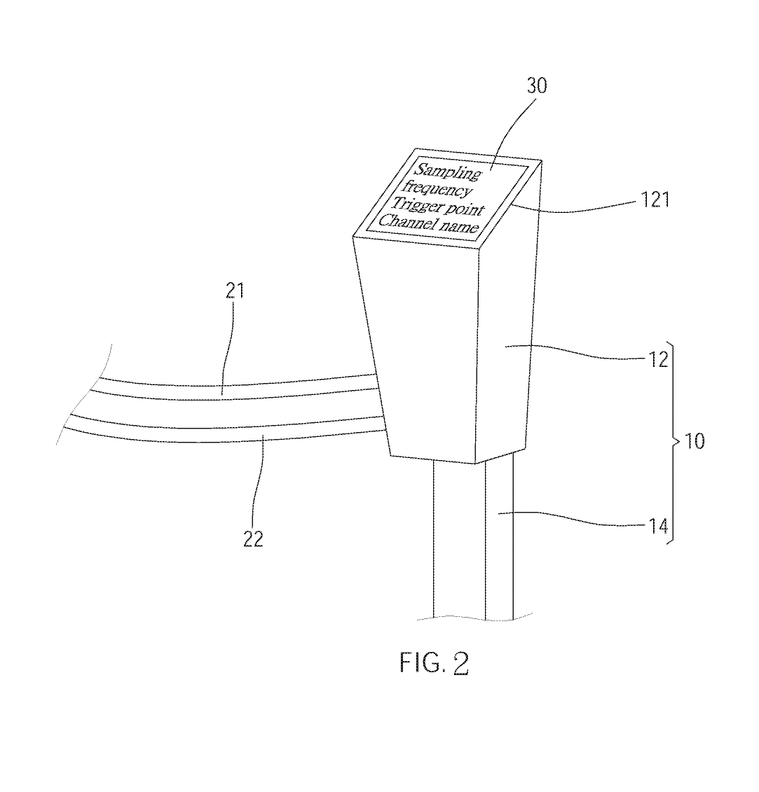

The probe 10 includes a holding portion 12 and a detecting portion 14. As shown in FIG. 2, the holding portion 12 is adapted to be held, and is made of an insulating material, wherein a top of the holding portion 12 is an inclined surface 121. The detecting portion 14 is made of a conductive material, and is provided on a bottom of the holding portion 12. In the current embodiment, an end of the detecting portion 14 is tapered to form a tip, which is adapted to abut against a tested portion of the DUT 100, retrieving digital signals outputted by the DUT 100. However, the detecting portion 14 could have different shapes or designs in other embodiments to meet specific requirements. For example, the detecting portion 14 could be a crocodile clip instead.

The display 30 is provided on the inclined surface 121 of the holding portion 12. The display 30 and the detecting portion 14 are at opposite ends of the holding portion 12. In other words, the display is provided on the top of the holding portion 12, while the detecting portion 14 is provided on the bottom thereof. In the current embodiment, the display 30 is an LCD. However, the display 30 could be a component capable of displaying characters in practice.

An end of the first transmission line 21 and an end of the second transmission line 22 are respectively provided in the holding portion 12, and are electrically connected to the detecting portion 14 and the display 30, respectively. By providing the end of the first transmission line 21 and the end of the second transmission line 22 in the holding portion 12, the wires (i.e., the first transmission line 21 and the second transmission line 22) could be kept neat, which would help not to hinder the operation of the R&D engineer, for the holding portion 12, the first transmission line 21, and the second transmission line 22 have become an inseparable component. In practice, a portion of each of the first transmission line 21 and the second transmission line 22 exposed out of the holding portion 12 could be wrapped in a sleeve (not shown) instead, which could also serve the same function as described herein.

A plurality of parameters are set in the processing unit 40, including waveforms, frequencies, trigger points, channels for retrieving signals, etc. The processing unit 40 is electrically connected to the first transmission line 21 and the second transmission line 22, and is adapted to be electrically connected to the computer 200. In this way, when the detecting portion 14 of the probe 10 abuts against the tested portion of the DUT 100, digital signals retrieved by the probe 10 would be transmitted to the processing unit 40 through the first transmission line 21, whereby the processing unit 40 could analyze the digital signals based on the parameters set therein to generate an analysis result. Once the analysis is completed, the analysis result including the information regarding, for example, waveforms, frequencies, trigger points, channels for retrieval, etc., would be transmitted to the computer 200, so that the analysis result could be displayed on a monitor 210 of the computer 200. Meanwhile, the processing unit 40 would also transmit a part of the analysis result which is deemed more informative for the R&D engineer, such as the information regarding sampling frequencies, trigger points, channel names, etc., to the holding portion 12 through the second transmission line 22, whereby said part of the analysis result could be shown on the display 30. In the embodiment, the processing unit 40 has a built-in compiler, which is adapted to compile said part of the analysis result generated by the processing unit 40 into corresponding I²C signals, which could be outputted through the second transmission line 22. On the other hand, the display 30 has a corresponding built-in interpreter, which is adapted to interpret the I²C signals transmitted through the second transmission line 22. In this way, said part of the analysis result (i.e., the information regarding sampling frequencies, trigger points, channel names in the current embodiment) compiled into I²C signals could be obtained and shown on the display 30, as illustrated in FIG. 2.

With such design, the R&D engineer could be quickly and accurately informed about some fundamental data of the retrieved digital signals through the display 30 while testing the DUT 100, which reduces the chance of incorrectly reading the parameters. Also, by respectively providing the detecting portion 14 and the display 30 on opposite ends of the holding portion 12, the display 30 would not be covered by hand when the R&D engineer holds the holding portion 14 with the detecting portion 14 abutting against the DUT 100 for testing. Furthermore, by providing the display 30 on the inclined surface 121 on the top of the holding portion 12, the R&D engineer could easily look right at the display 30 to read the displayed information, which greatly enhances the convenience of doing a test.

In summary, while using the logic analyzer, the R&D engineer could not only view the analysis result through the monitor 210 of the computer 200, but also directly read the information regarding the parameters shown on the display 30 of the probe 10, which is convenient and straightforward. As a result, the operation would become easy, and the work performance would be further improved.

It must be pointed out that the embodiments described above are only some preferred embodiments of the present invention. All equivalent structures which employ the concepts disclosed in this specification and the appended claims should fall within the scope of the present invention.

What is claimed is:

1. A logic analyzer, comprising:
a probe, which is adapted to abut against a device under test (DUT) to retrieve digital signals outputted by the DUT;
a first transmission line electrically connected to the probe;
a display provided on the probe;
a second transmission line, which is electrically connected to the display; and
a processing unit, which is electrically connected to the first transmission line and the second transmission line, and is adapted to be electrically connected to a computer, wherein a plurality of parameters are set in the processing unit; the processing unit receives the digital signals retrieved by the probe through the first transmission line, and analyzes the received digital signals based on the parameters set therein to generate an analysis result, which is transmitted to the computer to be displayed thereon; a part of the analysis result is transmitted to the display through the second transmission line to be shown thereon.

2. The logic analyzer of claim 1, wherein the probe has a holding portion and a detecting portion; the holding portion is made of an insulating material, and the display is provided on the holding portion; the detecting portion is made of a conductive material, and is connected to the holding portion, wherein the detecting portion is adapted to abut against the DUT.

3. The logic analyzer of claim 2, wherein an end of the first transmission line and an end of the second transmission line are respectively provided in the holding portion, and are connected to the detecting portion and the display, respectively.

4. The logic analyzer of claim 2, wherein the detecting portion and the display are respectively provided on two opposite ends of the holding portion.

5. The logic analyzer of claim 2, wherein an end of the holding portion has an inclined surface, and the display is provided on the inclined surface.

6. The logic analyzer of claim 1, wherein the processing unit has a compiler, which is adapted to compile said part of the analysis result generated by the processing unit to corresponding signals, which are outputted through the second transmission line; the display has an interpreter, which is adapted to interpret the signals transmitted by the second transmission line to obtain said part of the analysis result out from the signals, so as to display said part of the analysis result on the display.

7. The logic analyzer of claim 6, wherein the compiler compiles said part of the analysis result generated by the processing unit into I²C signals, and the interpreter is adapted to interpret the I²C signals to obtain said part of the analysis result out from the I²C signals.

8. The logic analyzer of claim 1, wherein the processing unit transmits one among a sampling frequency of the digital signals, a trigger point for retrieving the digital signals, and a channel name for retrieving the digital signals to the display through the second transmission line to be displayed thereon.

9. A probe for a logic analyzer, wherein the probe is adapted to abut against a device under test (DUT) to retrieve digital signals outputted by the DUT, and is adapted to transmit the digital signals to a processing unit of the logic analyzer for analyzing; the probe is characterized in that:
a display is provided on the probe, wherein a part of an analysis result generated by the processing unit is shown on the display.

10. The probe of claim 9, wherein the digital signals are transmitted to the processing unit through a first transmission line, and the display receives said part of the analysis result generated by the processing unit through a second transmission line.

11. The probe of claim 9, further comprising a holding portion and a detecting portion, wherein the holding portion is made of an insulating material; the display is provided on the holding portion; the detecting portion is made of a conductive material, and is connected to the holding portion, wherein the detecting portion is adapted to abut against the DUT.

12. The probe of claim 11, wherein the detecting portion and the display are respectively provided on two opposite ends of the holding portion.

13. The probe of claim 11, wherein an end of the holding portion has an inclined surface, and the display is provided on the inclined surface.
